(19) United States
(12) Patent Application Publication
(10) Pub. No.: US 2026/0063723 A1
(43) Pub. Date: Mar. 5, 2026

(54) BATTERY MANAGEMENT UNIT AND METHOD

(71) Applicants: HYUNDAI MOTOR COMPANY, Seoul (KR); KIA CORPORATION, Seoul (KR)

(72) Inventors: Cheol Beom Lim, Hwaseong-si (KR); Jin Woo Park, Hwaseong-si (KR); Yoon Sung Choi, Hwaseong-si (KR)

(73) Assignees: HYUNDAI MOTOR COMPANY, Seoul (KR); KIA CORPORATION, Seoul (KR)

(21) Appl. No.: 19/076,703

(22) Filed: Mar. 11, 2025

(30) Foreign Application Priority Data
Sep. 2, 2024 (KR) 10-2024-0118814

(51) Int. Cl. G01R 31/367; G01R 31/388; G01R 31/389; G01R 31/392; G01R 31/396

(52) U.S. Cl. CPC G01R 31/367; G01R 31/388; G01R 31/389; G01R 31/392; G01R 31/396

(57) ABSTRACT

A battery management unit and method are disclosed. The battery management unit includes a sensor, a first battery model, a second battery model, and a processor. The sensor measures a voltage of a battery. The first battery model and the second battery model are to estimate different characteristics of the battery based on a measurement voltage. The processor obtains a first terminal voltage corresponding to the measurement voltage based on the first battery model, obtains a second terminal voltage corresponding to the measurement voltage based on the second battery model, and fuses the first terminal voltage and the second terminal voltage to determine a final terminal voltage of battery.

### CROSS-REFERENCE TO RELATED APPLICATION

This application claims the benefit of and priority to Korean Patent Application No. 10-2024-0118814, filed in the Korean Intellectual Property Office on Sep. 2, 2024, the entire contents of which are incorporated herein by reference.

### TECHNICAL FIELD

The present disclosure relates to a battery management unit and to a method thereof, and more particularly, relates to technologies for determining a terminal voltage of a battery and performance using the terminal voltage.

### BACKGROUND

With diversity of electronic devices, there has been a gradual increase in battery use field. Recently, as electric vehicles or hybrid electric vehicles have appeared, there has been an increase in the use of batteries.

The performance of the battery as well as the state of charge (SOC) of the battery are very important for stability and driving performance of the electric vehicle. The performance of the battery may be determined using a state of health (SOH) or the like. The SOH of the battery may be determined based on a terminal voltage of the battery.

In general, the terminal voltage of the battery may be calculated using a battery model. The battery model may well inflect a specific characteristic of the battery depending on its type but may fail to well reflect a certain characteristic. Thus, a conventional method for measuring a terminal voltage of the battery or a conventional method for measuring performance of the battery has a limitation in reflecting all of characteristics of the battery according to various causes.

### SUMMARY

The present disclosure has been made to solve the above-mentioned problems occurring in the prior art while advantages achieved by the prior art are maintained intact.

Aspects of the present disclosure provide a battery management unit and a method for reflecting various characteristics of a battery to determine a state of the battery.

Other aspects of the present disclosure provide a battery management unit and a method for reflecting both of a direct current (DC)-based battery characteristic and an alternating current (AC)-based battery characteristic.

The technical problems to be solved by the present disclosure are not limited to the aforementioned problems. Any other technical problems not mentioned herein should be more clearly understood from the following description by those having ordinary skill in the art to which the present disclosure pertains.

According to an aspect of the present disclosure, a battery management unit may include a sensor, a first battery model, a second battery model, and a processor. The sensor may measure a voltage of a battery. The first battery model and the second battery model may be to estimate different characteristics of the battery based on a measurement voltage. The processor may obtain a first terminal voltage corresponding to the measurement voltage based on the first battery model, may obtain a second terminal voltage corresponding to the measurement voltage based on the second battery model, and may fuse the first terminal voltage and the second terminal voltage to determine a final terminal voltage of battery.

According to an embodiment, the first battery model and the second battery model may be pre-designed using different parameters based on a voltage change rate of the battery over time.

According to an embodiment, the processor may determine a first weight for the first battery model based on a first voltage error between the measurement voltage and the first terminal voltage. Further, the processor may determine a second weight for the second battery model based on a second voltage error between the measurement voltage and the second terminal voltage. The processor may also determine the final terminal voltage based on the first weight and the second weight.

According to an embodiment, the processor may determine a first covariance based on the first voltage error. The processor may further determine the first weight based on a probability that the first terminal voltage is generated based on the first covariance. Further, the processor may determine a second covariance based on the second voltage error. The processor may also determine the second weight based on a probability that the second terminal voltage is generated based on the second covariance.

According to an embodiment, the processor may determine a third terminal voltage in a third battery model based on the measurement voltage. The processor may also determine a third weight for the third battery model based on a third voltage error between the measurement voltage and the third terminal voltage. Further, the processor may determine the final terminal voltage of the battery based on the first to third weights.

According to an embodiment, the first battery model, the second battery model, and the third battery model may be a direct current (DC) model, an alternating current (AC) model, and an open circuit voltage (OCV) model, respectively.

According to an embodiment, the AC model may be designed based on AC impedance information obtained for each frequency by dividing current and voltage data over time into a frequency domain.

According to an embodiment, the processor may determine a terminal voltage matching a largest weight among the first to third weights as the final terminal voltage.

According to an embodiment, the processor may correct the first terminal voltage using the first weight to determine a first correction voltage. The processor may also correct the second terminal voltage using the second weight to determine a second correction voltage. The processor may also correct the third terminal voltage using the third weight to determine a third correction voltage. Further, the processor may determine the final terminal voltage based on the first correction voltage, the second correction voltage, and the third correction voltage.

According to an embodiment, the processor may determine a state of health (SOH) of the battery based on the final terminal voltage and may determine an abnormal state of the battery based on the SOH.

According to another aspect of the present disclosure, a battery management method may include: obtaining, by a sensor, a measurement voltage of a battery; obtaining, by a processor, a first terminal voltage corresponding to the measurement voltage based on a first battery model; obtaining, by the processor, a second terminal voltage corresponding to the measurement voltage based on a second battery model; and determining, by the processor, a final terminal voltage of the battery, by fusing the first and second terminal voltages.

According to an embodiment, the first battery model and the second battery model may be pre-designed using different parameters based on a voltage change rate of the battery over time.

According to an embodiment, determining the final terminal voltage of the battery may include: determining a first weight for the first battery model based on a first voltage error between the measurement voltage and the first terminal voltage in the first battery model; determining a second weight for the second battery model based on a second voltage error between the measurement voltage and the second terminal voltage in the second battery model; and determining the final terminal voltage based on the first weight and the second weight.

According to an embodiment, determining the first weight may include determining a first covariance based on the first voltage error, and determining the first weight based on a probability that the first terminal voltage is generated based on the first covariance. Determining the second weight may include determining a second covariance based on the second voltage error, and determining the second weight based on a probability that the second terminal voltage is generated based on the second covariance.

According to an embodiment, the battery management method may further include determining a third terminal voltage in a third battery model based on the measurement voltage, and determining a third weight for the third battery model based on a third voltage error between the measurement voltage and the third terminal voltage. Determining the final terminal voltage may include fusing the first to third weights.

According to an embodiment, the first battery model, the second battery model, and the third battery model may be a direct current (DC) model, an alternating current (AC) model, and an open circuit voltage (OCV) model, respectively.

According to an embodiment, the AC model may be designed based on AC impedance information obtained for each frequency by dividing current and voltage data over time into a frequency domain.

According to an embodiment, determining the final terminal voltage may include determining a terminal voltage matching a largest weight among the first to third weights as the final terminal voltage.

According to an embodiment, determining the final terminal voltage may include: correcting the first terminal voltage using the first weight to determine a first correction voltage; correcting the second terminal voltage using the second weight to determine a second correction voltage; correcting the third terminal voltage using the third weight to determine a third correction voltage; and determining the final terminal voltage based on the first correction voltage, the second correction voltage, and the third correction voltage.

According to an embodiment, the battery management method may further include determining a state of health (SOH) of the battery based on the final terminal voltage and determining an abnormal state of the battery based on the SOH.

### BRIEF DESCRIPTION OF THE DRAWINGS

The above and other objects, features, and advantages of the present disclosure should be more apparent from the following detailed description taken in conjunction with the accompanying drawings:

FIG. 1 illustrates a connection relationship of a battery management unit according to an embodiment of the present disclosure;

FIG. 2 illustrates a configuration of a battery management unit according to an embodiment of the present disclosure;

FIG. 3 is a flowchart of a battery management method according to an embodiment of the present disclosure;

FIG. 4 illustrates a battery management method according to an embodiment of the present disclosure;

FIG. 5 illustrates changes in current and voltage of a battery, which are obtained by a sensor device;

FIG. 6 schematically illustrates current and voltage change rates based on battery models according to embodiments of the present disclosure;

FIG. 7 illustrates a direct current (DC) model;

FIG. 8 illustrates an open circuit voltage (OCV) model;

FIG. 9 illustrates an impedance model;

FIG. 10 illustrates a method for setting parameters for a DC model and an OCV model;

FIG. 11 illustrates a frequency based on battery models according to embodiments of the present disclosure;

FIG. 12 illustrates a method for determining a final terminal voltage of a battery using battery models according to embodiments of the present disclosure;

FIG. 13 illustrates voltage errors;

FIG. 14 illustrates covariance; and

FIG. 15 illustrates a computing system according to an embodiment of the present disclosure.

### DETAILED DESCRIPTION

Hereinafter, some embodiments of the present disclosure are described in detail with reference to the drawings. In adding the reference numerals to the components of each drawing, it should be noted that the identical components are designated by the identical numerals even when they are displayed on other drawings. In addition, a detailed description of related known features or functions has been omitted in order not to unnecessarily obscure the gist of the present disclosure.

In describing the components of embodiment of the present disclosure, terms such as first, second, “A”, “B”, (a), (b), and the like may be used. These terms are only used to distinguish one element from another element, but do not limit the corresponding elements irrespective of the order or priority of the corresponding elements. Furthermore, unless otherwise defined, all terms including technical and scientific terms used herein have the same meaning as being generally understood by those having ordinary skill in the art to which the present disclosure pertains. Such terms as those defined in a generally used dictionary are to be interpreted as having meanings consistent with the contextual meanings in the relevant field of art. Such terms are not to be interpreted as having ideal or excessively formal meanings unless clearly defined as having such in the present application.

In the present disclosure, each phrase such as “A or B”, “at least one of A and B”, “at least one of A or B”, “A, B or C”, “at least one of A, B and C”, “at least one of A, B or C” and “at least one of A, B, or C, or a combination thereof” may include any one or all possible combinations of the items listed together in the corresponding one of the phrases. When a component, processor, model, module, unit, device, element, apparatus, or the like (i.e., an apparatus) of the present disclosure is described as having a purpose or performing an operation, function, or the like, the component, processor, model, module, unit, device, element, apparatus, or the like should be considered herein as being “configured to” meet that purpose or to perform that operation or function. Each component, processor, model, module, unit, device, element, apparatus, and the like may separately embody or be included with a processor and a memory, such as a non-transitory computer readable media, as part of the apparatus.

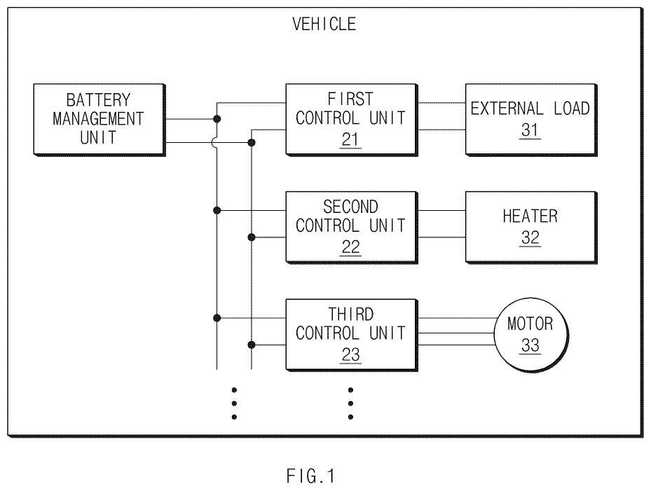

Hereinafter, embodiments of the present disclosure are described in detail with reference to FIGS. 1-15.

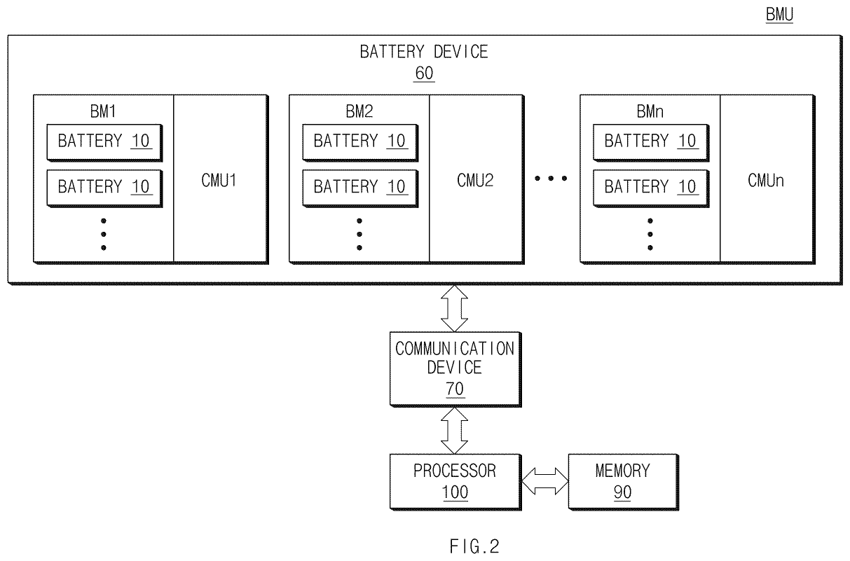

FIG. 1 is a drawing for describing a connection relationship of a battery management unit according to an embodiment of the present disclosure. FIG. 2 is a drawing illustrating a configuration of a battery management unit according to an embodiment of the present disclosure.

Referring to FIGS. 1 and 2, a battery management unit BMU according to an embodiment of the present disclosure may be loaded into a vehicle VEH to supply a voltage to control units 21, 22, and 23 in the vehicle VEH. For example, the first control unit 21 may supply a voltage to an external load 31. The second control unit 22 may supply a voltage to a heater 32, which may include a direct current/direct current (DC/DC) converter. The third control unit 23 may supply a voltage to a motor 33 for driving the vehicle VEH, which may include a direct current/alternating current (DC/AC) converter.

The battery management unit BMU according to an embodiment of the present disclosure may include a battery device 60, a communication device 70, sensor devices CMU1 to CMUn, and a processor 100.

The battery device 60 may include an n (where n is 2 or more natural numbers) number of battery modules BM1 to BMn. Each of the battery modules BM1 to BMn may include a plurality of batteries 10. Each of the batteries 10 may be referred to as a battery cell.

The sensor devices CMU1 to CMUn may match the battery modules BM1 to BMn one-to-one. The first CMU CMU1 may sense a voltage of the first battery module BM1. Furthermore, the sensor devices CMU1 to CMUn may obtain battery state information. The battery state information may be at least one of internal resistance of the battery 10, a leakage current of the battery 10, or a state of health (SOH) of the battery 10.

The communication device 70 may be for communication between the sensor devices CMU1 to CUMn and the processor 100, which may be implemented as a wired or wireless communication means.

For example, the communication device 70 may support short range communication, using at least one of Bluetooth, radio frequency identification (RFID), infrared data association (IrDA), ultra wideband (UWB), ZigBee, near field communication (NFC), wireless-fidelity (Wi-Fi), Wi-Fi Direct, and wireless universal serial bus (USB) technologies.

The structure of the battery device 60 and the sensor devices CMU1 to CMUn may be implemented as various embodiments other than the structure shown in FIG. 2.

Furthermore, when the processor 100 is located outside the vehicle VEH, the communication device 70 may perform wireless communication based on global system for mobile communication (GSM), code division multi access (CDMA), code division multi access 2000 (CDMA2000), enhanced voice-data optimized or enhanced voice-data only (EV-DO), wideband CDMA (WCDMA), high speed downlink packet access (HSDPA), high speed uplink packet access (HSUPA), long term evolution (LTE), long term evolution-advanced (LTE-A), or the like.

The processor 100 may diagnose abnormal states of the plurality of batteries 10. The processor 100 may determine terminal voltages of the batteries 10 to diagnose the abnormal states of the batteries 10. Hereinafter, the plurality of batteries 10 are collectively referred to as the battery 10.

The processor 100 may receive information about measurement voltages from the sensor devices CMU1 to CMUn to determine the terminal voltages of the batteries 10.

The processor 100 may determine terminal voltages in two or more battery models using the measurement voltage and may determine a final terminal voltage using the terminal voltages. According to an embodiment of the present disclosure, because the processor 100 is able to determine the final terminal voltage based on the two or more battery models, it may more accurately determine the final terminal voltage in response to various states of the battery 10.

A description is given below of a detailed embodiment of determining the final terminal voltage of the battery 10 according to an embodiment of the present disclosure.

An algorithm for an operation of the processor 100 may be stored in a memory 90. The memory 90 may include a hard disk drive, a flash memory, an electrically erasable programmable read-only memory (EEPROM), a static random access memory (SRAM), a ferro-electric RAM (FRAM), a phase-change RAM (PRAM), a magnetic RAM (MRAM), a dynamic RAM (DRAM), a synchronous DRAM (SDRAM), a double date rate-SDRAM (DDR-SDRAM), or the like.

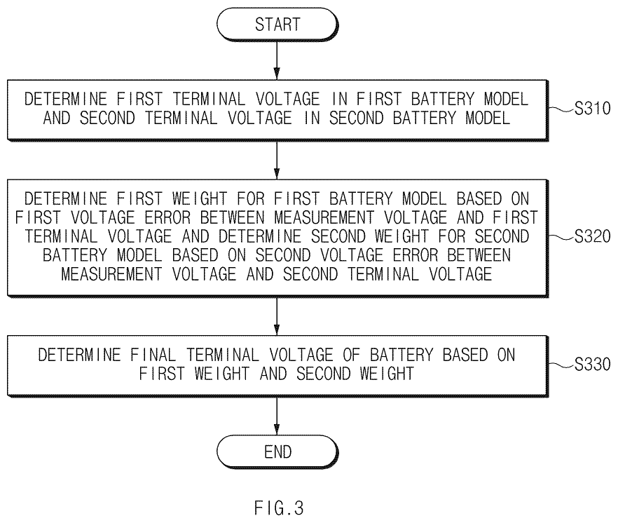

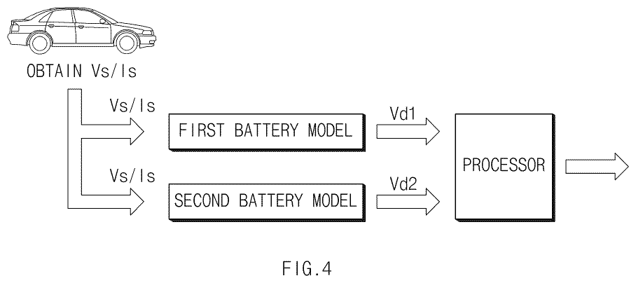

FIG. 3 is a flowchart for describing a battery management method according to an embodiment of the present disclosure. FIG. 4 is a drawing illustrating a battery management method according to an embodiment of the present disclosure. A procedure shown in FIG. 3 may be performed by a processor 100.

The battery management method according to an embodiment of the present disclosure is described with reference to FIGS. 3 and 4.

In S310, the processor 100 may obtain a measurement voltage depending on discharging of a battery 10 and may determine a first terminal voltage in a first battery model and a second terminal voltage in a second battery model using the measurement voltage.

To this end, while a vehicle is operating, the processor 100 may check a measurement voltage of the battery 10 in real time.

The processor 100 may determine the first terminal voltage corresponding to the measurement voltage of the battery 10 based on the first battery model and may determine the second terminal voltage corresponding to the measurement voltage of the battery 10 based on the second battery model.

The first battery model and the second battery model may be pre-designed using different parameters. The first battery model and the second battery model may be divided and designed on the basis of a voltage change rate of the battery 10 over time. For example, the first battery model may be constructed to more accurately reflect a state of the battery 10, a voltage of which quickly changes. The second battery model may be constructed to reflect a state of the battery 10, a voltage of which more slowly changes than the first battery model.

Alternatively, the first battery model may be a DC-based battery model and the second battery model may be an AC-based battery model.

In S320, the processor 100 may determine a first weight for the first battery model based on a first voltage error between the measurement voltage and the first terminal voltage and may determine a second weight for the second battery model based on a second voltage error between the measurement voltage and the second terminal voltage.

The first voltage error may be determined based on a difference between the measurement voltage and the first terminal voltage and the second voltage error may be determined based on a difference between the measurement voltage and the second terminal voltage.

The smaller the first voltage error, the larger the first weight may be set to be. The larger the first voltage error, the smaller the first weight may be set to be. The smaller the second voltage error, the larger the second weight may be set to be. The larger the second voltage error, the smaller the second weight may be set to be.

Alternatively, the first weight may be determined based on a probability that the first terminal voltage may be generated in a probability that the first voltage error may be generated. The second weight may be determined based on a probability that the second terminal voltage may be generated in a probability that the second voltage error may be generated. To this end, the processor 100 may use a predetermined optional probability density function. The optional probability density function may be used to determine the probability that the first terminal voltage may be generated based on covariance between the first terminal voltage and the first voltage error and determine the first weight. Furthermore, the optional probability density function may be used to determine the probability that the second terminal voltage may be generated based on covariance between the second terminal voltage and the second voltage error and determine the second weight.

In S330, the processor 100 may determine a final terminal voltage of the battery 10 based on the first weight and the second weight.

A description is given below of a method for determining a final terminal voltage based on that the first terminal voltage for the first battery model is V1, that the first weight is W1, that the second terminal voltage for the second battery model is V2, and that the second weight is W2.

The processor 100 may determine a terminal voltage corresponding to a largest weight between the first weight and the second weight as the final terminal voltage. For example, when the first weight is greater than the second weight, the processor 100 may determine the first terminal voltage as the final terminal voltage of the battery 10.

Alternatively, the processor 100 may reflect the first weight in the first terminal voltage to determine a first correction voltage and may reflect the second weight in the second terminal voltage to determine a second correction voltage. The processor 100 may determine the final terminal voltage based on the first correction voltage and the second correction voltage. For example, the processor 100 may determine the first correction voltage based on V1×W1 and may determine the second correction voltage based on V2×W2. The processor 100 may add the first correction voltage and the second correction voltage to determine the final terminal voltage.

The magnitude obtained by adding the first weight and the second weight may be set to 1.

The first battery model and the second battery model in the battery management method according to an embodiment of the present disclosure may be designed using different parameters. For example, the first battery model and the second battery model may be designed using parameters divided based on a voltage change rate of the battery over time.

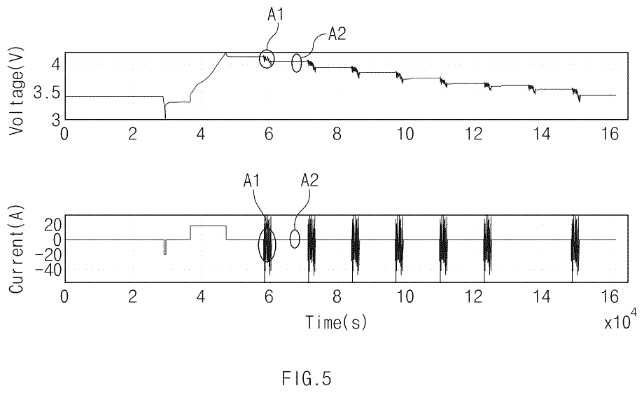

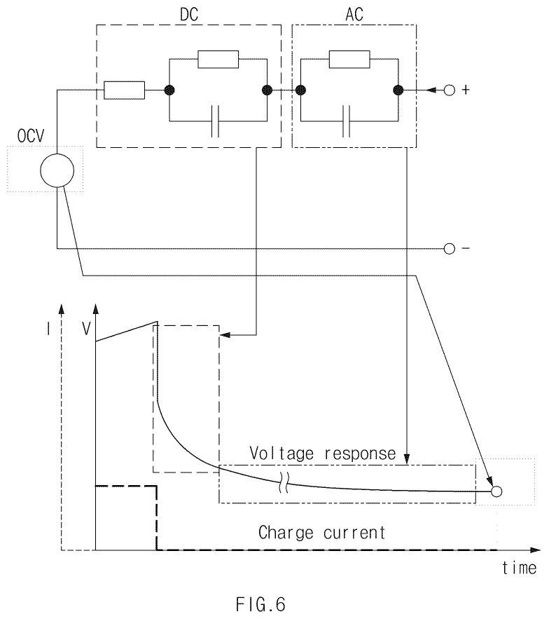

FIGS. 5 and 6 are drawings for describing a method for dividing current and voltage data and designing battery models. FIG. 5 is a drawing illustrating changes in current and voltage of a battery, which are obtained by a sensor device. FIG. 6 is a drawing schematically illustrating current and voltage change rates according to battery models according to embodiments of the present disclosure.

A description is given below of a method for designing different battery models based on current and battery data with reference to FIGS. 5 and 6.

As shown in FIGS. 5 and 6, the voltage of a battery 10 may change according to the current of the battery 10 in an operation duration of a vehicle.

The current and the voltage of the battery 10, which are obtained by sensor devices CMU1 to CUMn, may vary over time. Current and voltage data according to the operation of the vehicle may be divided into a first interval A1 indicating periodicity and a second interval A2 in which an almost constant level is maintained.

The current and voltage data in the first interval A1 may be used to design a DC model.

Furthermore, the current and voltage data in the first interval A1 may be transformed into a frequency domain and may be used to design an impedance model. The impedance model may be designed using data obtained by transforming DC-based time-series data into a frequency domain through Fourier transform.

The second interval A2 may correspond to a no-load voltage interval and may be used to design an open circuit voltage (OCV) model.

A description is given in detail below of each battery model.

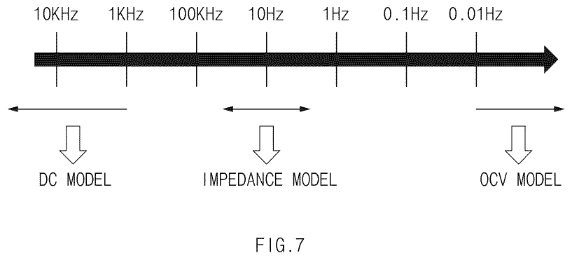

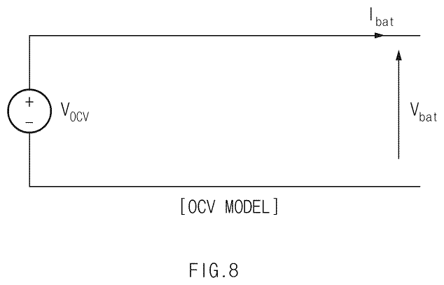

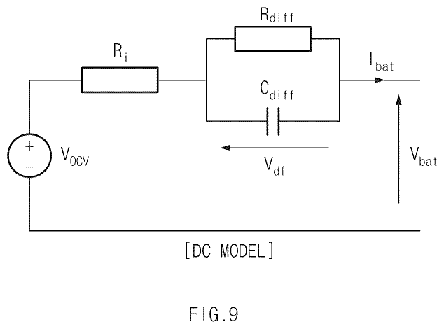

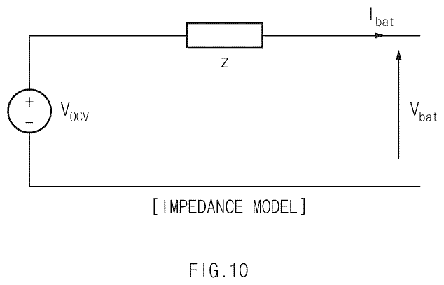

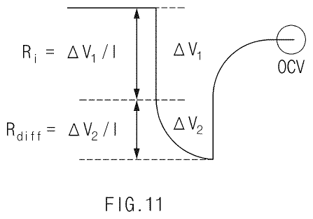

FIG. 7 is a drawing illustrating a DC model. FIG. 8 is a drawing illustrating an OCV model. FIG. 9 is a drawing illustrating an impedance model. FIG. 10 is a drawing for describing a method for setting parameters for a DC model and an OCV model. FIG. 11 is a drawing for describing a frequency according to battery models.

Hereinafter, a description is given of each battery model.

Referring to FIG. 7, the DC model may be modeled using parameters Rᵢ, R_{diff}, C_{diff}, and Vocv.

Rᵢ may refer to the resistance generated in a process in which the lithium-ion of a battery 10 deviates from the electrode, which may be internal resistance. R_{diff} may refer to resistance generated in a process in which the lithium-ion of the battery 10 moves into the electrolyte. C_{diff} may refer to the formation of an electrical double layer according to an oxidation-reduction reaction and may refer to the capacitance between the electrode and the electrolyte. Vocv may refer to the terminal voltage in the chemical equilibrium in the battery 10.

The DC model may reflect a characteristic of current and voltage data with a frequency component of 1 KHz or more.

Referring to FIG. 8, the OCV model may be modeled based on Vocv. In detail, the OCV model may be modeled based on an open voltage corresponding to a state of charge (SOC).

The OCV model may reflect a characteristic of current and voltage data with a frequency component of 0.01 Hz or more.

Referring to FIG. 9, the impedance model may be modeled based on impedance information indicating an electrochemical internal state of the battery 10.

The impedance model may be modeled using AC impedance information of the battery 10 based on electrochemical impedance spectroscopy (EIS). The impedance model may be generated based on a frequency characteristic in a range in which the impedance model has a higher frequency than the DC model and has a lower frequency than the OCV model.

The impedance model may be designed based on current and voltage data according to the discharging of the battery 10, which is obtained in the vehicle operation process shown in FIG. 5.

Discrete wavelet transform (DWT) and short-time Fourier transform (STFT) may be performed for the current and voltage data to obtain the impedance model.

The DWT may be a procedure for noise cancellation. Data may be decomposed according to a frequency level while the noise of the current and voltage data is canceled through the DWT.

The STFT may be to extract a frequency characteristic. After data for each frequency is extracted using the DWT, a time domain signal may be transformed into a frequency domain signal using the STFT. Because current and voltage data obtained in real time while a vehicle is operating is difficult to perform periodic extraction for each frequency in a long time interval, a current and voltage frequency characteristic may be obtained using the STFT.

The impedance model may be designed based on AC impedance in which signals, the DWT and the STFT of which are performed, are obtained for each frequency based on Ohm's law.

The impedance model may reflect a characteristic of current and voltage data with a frequency component of about 1 Hz to 50 Hz.

A first battery model may be any one of the DC model, the OCV model, or the impedance model. A second battery model may be different from the first battery model, which may be any one of the DC model, the OCV model, or the impedance model. For example, when the first battery model is the DC model, the second battery model may be the OCV model and the impedance model.

A first weight for the first battery model may be determined based on a voltage error between a measurement voltage and a first terminal voltage. A second weight for the second battery model may be determined based on a voltage error between the measurement voltage and a second terminal voltage.

A processor 100 may determine a probability that the first voltage error may be generated based on first covariance as the first weight. The first covariance may be covariance between the first terminal voltage and the first voltage error.

Furthermore, the processor 100 may determine a probability that the second voltage error may be generated based on second covariance as the second weight. The second covariance may be covariance between the second terminal voltage and the second voltage error.

An embodiment of the present disclosure may fuse weights of two or more battery models to determine a final terminal voltage. For example, an embodiment of the present disclosure may determine the final terminal voltage using three battery models.

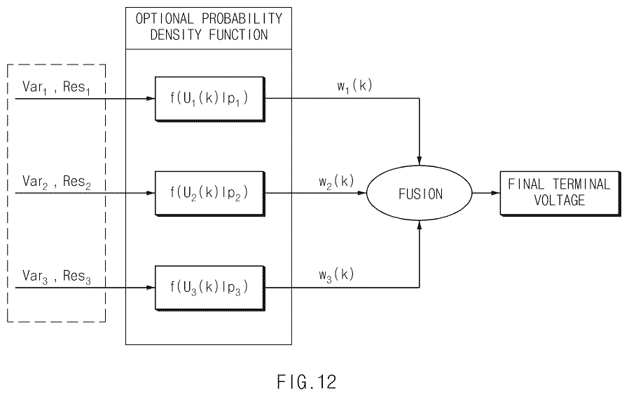

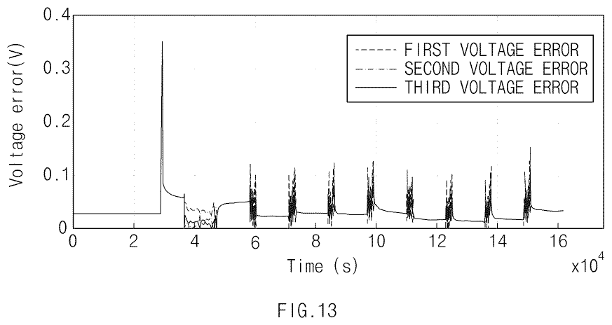

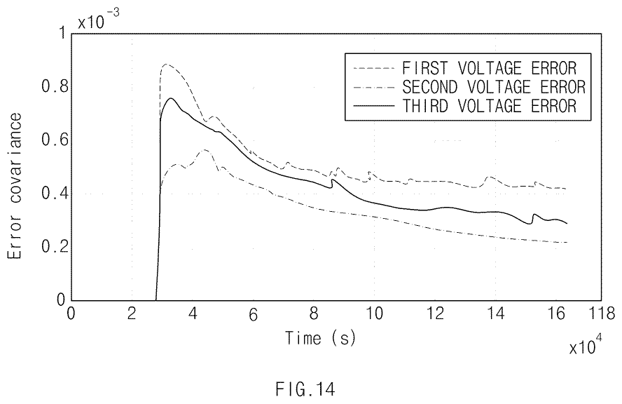

FIG. 12 is a drawing for describing a method for determining a final terminal voltage of a battery using first to third battery models according to embodiments of the present disclosure. FIG. 13 is a drawing illustrating voltage errors. FIG. 14 is a drawing illustrating covariance.

Referring to FIG. 12, a final terminal voltage of a battery 10 according to an embodiment of the present disclosure may be determined using an optional probability density function.

To use the optional probability density function, a processor 100 may determine a first voltage error Res₁, a second voltage error Res₂, and a third voltage error Res₃ and may determine first covariance Var₁, second covariance Var₂, and third covariance Var₃.

The first voltage error Res₁ may refer to a difference between a measurement voltage and a first terminal voltage in a first battery model. The second voltage error Res₂ may refer to a difference between the measurement voltage and a second terminal voltage in a second battery model. The third voltage error Res₃ may refer to a difference between the measurement voltage and a third terminal voltage in a third battery model. The first battery model may be a DC model. The second battery model may be an impedance model. The third battery model may be an OCV model.

The first voltage error Res₁, the second voltage error Res₂, and the third voltage error Res₃ obtained by the processor 100 may be represented as FIG. 13.

The first covariance Var₁ may be a value obtained by squaring and averaging the first voltage error. The second covariance Var₂ may be a value obtained by squaring and averaging the second voltage error. The third covariance Var₃ may be a value obtained by squaring and averaging the third voltage error.

The first covariance Var₁, the second covariance Var₂, and the third covariance Var₃ obtained by the processor 100 may be represented as FIG. 14.

The processor 100 may determine a first weight W₁, a second weight W₂, and a third weight W₃ based on the optional probability density function capable of being represented as Equation 1 below.

$$f ( {U}_{t} ( k ) \vert {P}_{n} ) = \frac{1}{( 2 π ) 1 / 2 {Var}_{n}^{1 / 2} ( k )} \times exp ( - {Res}_{n}^{T} ( k ) {Var}_{n}^{- 1} ( k ) {Res}_{n} ( k ) / 2 ) \qquad [ Equation 1 ]$$

In Equation 1 above, Ut may be any one of the first terminal voltage U₁, the second terminal voltage U₂, or the third terminal voltage U₃. Resₙ may be any one of the first voltage error Res₁, the second voltage error Res₂, or the third voltage error Res₃. Furthermore, Varₙ may be any one of the first covariance Var₁, the second covariance Var₂, or the third covariance Var₃.

Referring to Equation 1 above and FIG. 12, the processor 100 may determine the first weight W₁ based on a probability that the first terminal voltage U₁ may be generated on condition of a probability density function of the first battery model.

The processor 100 may determine the second weight W₂ based on a probability that the second terminal voltage U₂ may be generated on condition of a probability density function of the second battery model.

The processor 100 may determine the third weight W₃ based on a probability that the third terminal voltage U₃ may be generated on condition of a probability density function of the third battery model.

The processor 100 may fuse the first weight W₁, the second weight W₂, and the third weight W₃ to determine a final terminal voltage. The sum of the first weight W₁, the second weight W₂, and the third weight W₃ may be 1.

According to an embodiment, the processor 100 may determine a terminal voltage matching a weight with the largest value among the first weight W₁, the second weight W₂, and the third weight W₃ as the final terminal voltage. The first weight W₁ may match the first terminal voltage U₁. The second weight W₂ may match the second terminal voltage U₂. The third weight W₃ may match the third terminal voltage U₃. According to an embodiment, when the first weight W₁ among the first weight W₁, the second weight W₂, and the third weight W₃ is the largest value, the processor 100 may determine the first terminal voltage as the final terminal voltage.

According to another embodiment, when the weight indicating the largest value is greater than the sum of the other two weights, the processor 100 may determine a terminal voltage matching the largest weight as the final terminal voltage. For example, when the first weight W₁ indicates the largest value and is greater than the sum of the first weight W₁, the second weight W₁, and the third weight W₃, the processor 100 may determine the first terminal voltage as the final terminal voltage.

According to another embodiment, the processor 100 may reflect weights to correct terminal voltages and may add the corrected terminal voltages to determine the final terminal voltage. For example, the processor 100 may multiply the first terminal voltage and the first weight W₁ to determine a first correction voltage. The processor 100 may multiply the second terminal voltage and the first weight W₂ to determine a second correction voltage. The processor 100 may multiply the third terminal voltage and the third weight W₃ to determine a third correction voltage. The processor 100 may add the first correction voltage, the second correction voltage, and the third correction voltage to obtain the final terminal voltage.

Furthermore, according to an embodiment of the present disclosure, the processor 100 may determine a SOH of the battery 10 based on the final terminal voltage and may determine an abnormal state of the battery 10 based on the SOH of the battery 10. The procedure of determining the abnormal state of the battery 10 may be a procedure of determining performance of the battery 10 or determining whether an error in the battery 10 occurs.

The procedure of determining the SOH of the battery 10 may include a procedure of verifying SOH estimation performance. The procedure of verifying the SOH estimation performance of the battery 10 may use a method for comparing measurement capacity of the battery 10 with estimation capacity of the battery 10. The measurement capacity of the battery 10 may be to measure a current of the battery 10 and determine capacity of the battery 10 using a current integral method. The estimation capacity of the battery 10 may be capacity derived using a preset SOH estimation algorithm. When an error rate between the measurement capacity and the estimation capacity is within a certain level, the processor 100 may determine that performance of estimating the capacity of the battery 10 is excellent.

The procedure of determining the abnormal state of the battery 10 may be a procedure of generating error classification data based on impedance extraction. According to an embodiment of the present disclosure, the processor 100 may reflect a chemical change characteristic in the battery 10 using an impedance model, as well as accurately predicting a change in voltage of the battery 10 based on a DC model. Thus, according to an embodiment of the present disclosure, the processor 100 may more accurately perform abnormal state determination using the chemical change characteristic of the battery 10.

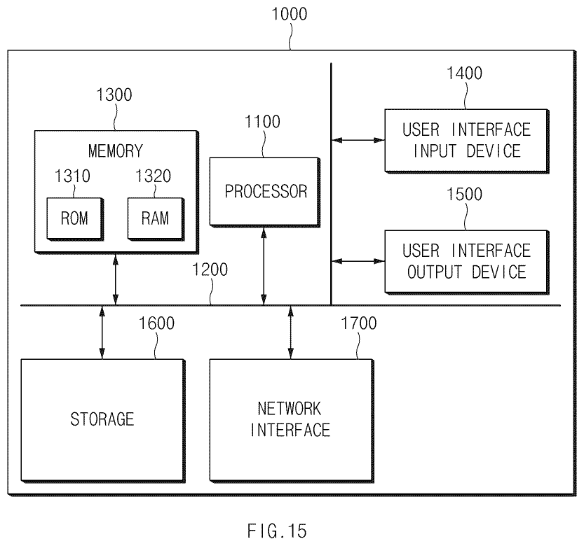

FIG. 15 illustrates a computing system according to an embodiment of the present disclosure.

Referring to FIG. 15, a computing system 1000 may include at least one processor 1100, a memory 1300, a user interface input device 1400, a user interface output device 1500, storage 1600, and a network interface 1700, which are connected with each other via a bus 1200.

The processor 1100 may be a central processing unit (CPU) or a semiconductor device that processes instructions stored in the memory 1300 and/or the storage 1600. The memory 1300 and the storage 1600 may include various types of volatile or non-volatile storage media. For example, the memory 1300 may include a read only memory (ROM) 1310 and a random access memory (RAM) 1320.

Accordingly, the operations of the method or algorithm described in connection with embodiments disclosed in the specification may be directly implemented with a hardware module, a software module, or a combination of the hardware module and the software module, which is executed by the processor 1100. The software module may reside on a storage medium (i.e., the memory 1300 and/or the storage 1600) such as a RAM, a flash memory, a ROM, an EPROM, an EEPROM, a register, a hard disc, a removable disk, and a compact disk (CD)-ROM.

The storage medium may be coupled to the processor 1100. The processor 1100 may read out information from the storage medium and may write information in the storage medium. Alternatively, the storage medium may be integrated with the processor 1100. The processor and the storage medium may reside in an application specific integrated circuit (ASIC). The ASIC may reside within a user terminal. In another case, the processor and the storage medium may reside in the user terminal as separate components.

According to an embodiment of the present disclosure, the battery management unit may fuse characteristics of two or more battery models to obtain a battery terminal voltage, thus reflecting various battery characteristics to obtain a more accurate battery terminal voltage.

Furthermore, according to an embodiment of the present disclosure, the battery management unit may fuse a battery model for reflecting a DC characteristic of the battery and a battery model for reflecting an AC characteristic to obtain a terminal voltage of the battery, thus obtaining a more accurate battery terminal voltage.

In addition, various effects ascertained directly or indirectly through the present disclosure may be provided.

Hereinabove, although the present disclosure has been described with reference to embodiments and the accompanying drawings, the present disclosure is not limited thereto, but may be variously modified and altered by those having ordinary skill in the art to which the present disclosure pertains without departing from the spirit and scope of the present disclosure claimed in the following claims.

Therefore, embodiments described in the present disclosure are not intended to limit the technical ideas of the present disclosure. The scope of the technical ideas of the present disclosure is not limited by the disclosed embodiments. The scope of the present disclosure should be construed based on the accompanying claims. All the technical ideas within the scope equivalent to the claims should be interpreted as being included in the claims of the present disclosure.

What is claimed is:

1. A battery management unit, comprising:
a sensor configured to obtain a measurement voltage of a battery;
a first battery model and a second battery model configured to estimate different characteristics of the battery based on the measurement voltage, respectively; and
a processor configured to
obtain a first terminal voltage corresponding to the measurement voltage based on the first battery model,
obtain a second terminal voltage corresponding to the measurement voltage based on the second battery model, and
fuse the first terminal voltage and the second terminal voltage to determine a final terminal voltage of the battery.

2. The battery management unit of claim 1, wherein the first battery model and the second battery model are pre-designed using different parameters based on a voltage change rate of the battery over time.

3. The battery management unit of claim 1, wherein the processor is further configured to:
determine a first weight for the first battery model based on a first voltage error between the measurement voltage and the first terminal voltage;
determine a second weight for the second battery model based on a second voltage error between the measurement voltage and the second terminal voltage; and
determine the final terminal voltage based on the first weight and the second weight.

4. The battery management unit of claim 3, wherein the processor is further configured to:
determine a first covariance based on the first voltage error;
determine the first weight based on a probability that the first terminal voltage is generated based on the first covariance;
determine second covariance based on the second voltage error; and
determine the second weight based on a probability that the second terminal voltage is generated based on the second covariance.

5. The battery management unit of claim 3, wherein the processor is further configured to:
determine a third terminal voltage in a third battery model based on the measurement voltage;
determine a third weight for the third battery model based on a third voltage error between the measurement voltage and the third terminal voltage; and
determine the final terminal voltage of the battery based on the first to third weights.

6. The battery management unit of claim 5, wherein the first battery model, the second battery model, and the third battery model are a direct current (DC) model, an alternating current (AC) model, and an open circuit voltage (OCV) model, respectively.

7. The battery management unit of claim 6, wherein the AC model is designed based on AC impedance information obtained for each frequency by dividing current and voltage data over time into a frequency domain.

8. The battery management unit of claim 5, wherein the processor is further configured to:
determine a terminal voltage matching a largest weight among the first to third weights as the final terminal voltage.

9. The battery management unit of claim 5, wherein the processor is further configured to:
correct the first terminal voltage using the first weight to determine a first correction voltage;
correct the second terminal voltage using the second weight to determine a second correction voltage;
correct the third terminal voltage using the third weight to determine a third correction voltage; and
determine the final terminal voltage based on the first correction voltage, the second correction voltage, and the third correction voltage.

10. The battery management unit of claim 1, wherein the processor is further configured to:
determine a state of health (SOH) of the battery based on the final terminal voltage; and
determine an abnormal state of the battery based on the SOH.

11. A battery management method, comprising:
obtaining, by a sensor, a measurement voltage of a battery;
obtaining, by a processor, a first terminal voltage corresponding to the measurement voltage based on a first battery model;
obtaining, by the processor, a second terminal voltage corresponding to the measurement voltage based on a second battery model; and
determining, by the processor, a final terminal voltage of the battery, by fusing the first and second terminal voltages.

12. The battery management method of claim 11, wherein the first battery model and the second battery model are pre-designed using different parameters based on a voltage change rate of the battery over time.

13. The battery management method of claim 11, wherein determining the final terminal voltage of the battery includes:
determining a first weight for the first battery model based on a first voltage error between the measurement voltage and the first terminal voltage in the first battery model;
determining a second weight for the second battery model based on a second voltage error between the measurement voltage and the second terminal voltage in the second battery model; and
determining the final terminal voltage based on the first weight and the second weight.

14. The battery management method of claim 13, wherein determining the first weight includes:
determining a first covariance based on the first voltage error; and
determining the first weight based on a probability that the first terminal voltage is generated based on the first covariance, and
wherein determining the second weight includes:
determining a second covariance based on the second voltage error; and
determining the second weight based on a probability that the second terminal voltage is generated based on the second covariance.

15. The battery management method of claim 13, further comprising:
determining a third terminal voltage in a third battery model based on the measurement voltage; and
determining a third weight for the third battery model based on a third voltage error between the measurement voltage and the third terminal voltage,
wherein determining the final terminal voltage includes fusing the first to third weights.

16. The battery management method of claim 15, wherein the first battery model, the second battery model, and the third battery model are a direct current (DC) model, an alternating current (AC) model, and an open circuit voltage (OCV) model, respectively.

17. The battery management method of claim 16, wherein the AC model is designed based on AC impedance information obtained for each frequency by dividing current and voltage data over time into a frequency domain.

18. The battery management method of claim 15, wherein determining the final terminal voltage includes:
determining a terminal voltage matching a largest weight among the first to third weights as the final terminal voltage.

19. The battery management method of claim 15, wherein determining the final terminal voltage includes:
correcting the first terminal voltage using the first weight to determine a first correction voltage;
correcting the second terminal voltage using the second weight to determine a second correction voltage;
correcting the third terminal voltage using the third weight to determine a third correction voltage; and
determining the final terminal voltage based on the first correction voltage, the second correction voltage, and the third correction voltage.

20. The battery management method of claim 11, further comprising:
determining a state of health (SOH) of the battery based on the final terminal voltage; and
determining an abnormal state of the battery based on the SOH.
